(19) United States
(12) Patent Application Publication
(10) Pub. No.: US 2026/0180582 A1
(43) Pub. Date: Jun. 25, 2026

(54) ANALOG BUFFER DEVICE

(71) Applicant: REALTEK SEMICONDUCTOR CORPORATION, HSINCHU (TW)

(72) Inventor: SHIH-HSIUNG HUANG, HSINCHU (TW)

(21) Appl. No.: 19/413,438

(22) Filed: Dec. 9, 2025

(30) Foreign Application Priority Data
Dec. 23, 2024 (TW) 113150220

(51) Int. Cl. H03K 19/0185

(52) U.S. Cl. CPC H03K 19/018528

(57) ABSTRACT

An analog buffer device includes a first source follower circuit and a second source follower circuit. The first source follower is circuit configured to generate a first output signal according to a first input signal. The second source follower circuit is configured to generate a second output signal according to a second input signal, in which the first source follower circuit and the second source follower circuit are coupled in series and coupled between a first power node and a second power node, the first power node receives a first power voltage, and the second power node receives a second power voltage.

### BACKGROUND OF THE INVENTION

### 1. Field of the Invention

The present disclosure relates to an analog buffer device, particularly to an analog buffer device that may use the same biasing current to generate output signals.

### 2. Description of Related Art

A source follower may provide a unity voltage gain, so that the source follower may operate as a buffer for an analog signal to increase the driving capability of the analog signal. In existing applications, when buffered signals are to be provided, buffers are needed to separately provide the buffered signals, where the buffers are usually independently arranged. Thus, the buffers are biased by different biasing currents, thereby resulting in increased power consumption.

### SUMMARY OF THE INVENTION

In some aspects, an object of the present disclosure is to, but not limited to, provide an analog buffer device that may use the same current bias to generate output signals, so as to make an improvement to the prior art.

In some aspects, an analog buffer device includes a first source follower circuit and a second source follower circuit. The first source follower is circuit configured to generate a first output signal according to a first input signal. The second source follower circuit is configured to generate a second output signal according to a second input signal, in which the first source follower circuit and the second source follower circuit are coupled in series and coupled between a first power node and a second power node, the first power node receives a first power voltage, and the second power node receives a second power voltage.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a schematic diagram of an analog buffer device according to some embodiments of the present disclosure.

FIG. 2 illustrates a schematic diagram of an analog buffer device according to some embodiments of the present disclosure.

FIG. 3 illustrates a schematic diagram of an analog buffer device according to some embodiments of the present disclosure.

FIG. 4 illustrates a schematic diagram of an analog buffer device according to some embodiments of the present disclosure.

FIG. 5 illustrates a schematic diagram of an analog buffer device according to some embodiments of the present disclosure.

FIG. 6 illustrates a schematic diagram of an analog buffer device according to some embodiments of the present disclosure.

FIG. 7 illustrates a schematic diagram of an analog buffer device according to some embodiments of the present disclosure.

FIG. 8 illustrates a schematic diagram of an analog buffer device according to some embodiments of the present disclosure.

FIG. 9 illustrates a schematic diagram of a level shifter circuit according to some embodiments of the present disclosure.

FIG. 10 illustrates a schematic diagram of a level shifter circuit according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuit” may indicate an object, which is formed with one or more transistors and/or one or more active/passive elements according to a specific arrangement, for processing signals.

As used herein, the term "and/or" includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, similar/identical elements in various figures are designated with the same reference number.

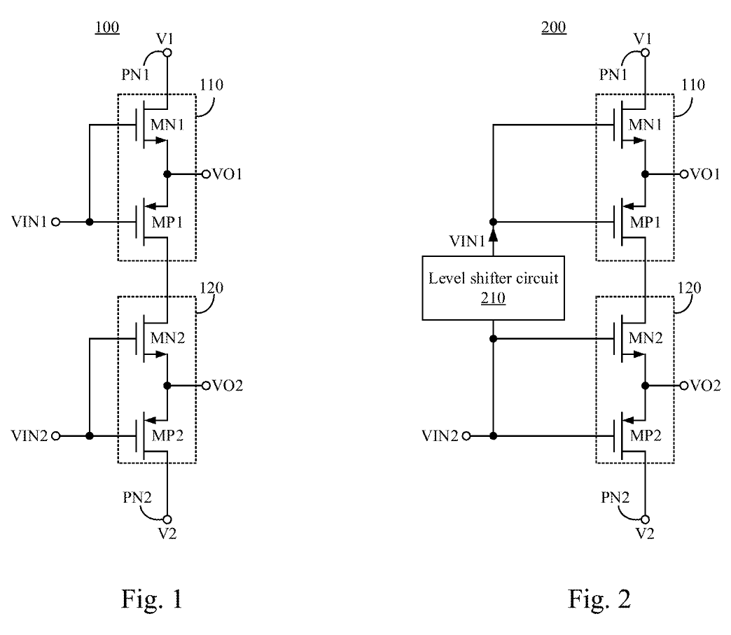

FIG. 1 illustrates a schematic diagram of an analog buffer device 100 according to some embodiments of the present disclosure. The analog buffer device 100 includes a source follower circuit 110 and a source follower circuit 120. The source follower circuit 110 and the source follower circuit 120 are coupled in series and coupled between a power node PN1 and a power node PN2. The power node PN1 receives a power voltage V1, the power node PN2 receives a power voltage V2, and the power voltage V1 is higher than the power voltage V2. With the above arrangement, the source follower circuit 110 and the source follower circuit 120 may be biased by the same current and may provide output signals having different direct current (DC) levels (for example, an output signal VO1 and an output signal VO2). In some embodiments, an input signal VIN1 and an input signal VIN2 may be the same signal.

The source follower circuit 110 may generate an output signal VO1 according to the input signal VIN1, and a source follower circuit 120 may generate an output signal VO2 according to the input signal VIN2. In greater detail, the source follower circuit 110 includes a transistor MN1 and a transistor MP1, and the source follower circuit 120 includes a transistor MN2 and a transistor MP2. A first terminal of the transistor MN1 (e.g., a drain) is coupled to the power node PN1 to receive the power voltage V1, a second terminal of the transistor MN1 (e.g., a source) is coupled to a first terminal of the transistor MP1 (e.g., source) to generate the output signal VO1, and a control terminal of the transistor MN1 (e.g., gate) receives the input signal VIN1. A second terminal of the transistor MP1 (e.g., drain) is coupled to the source follower circuit 120, and a control terminal of the transistor MP1 (e.g., gate) receives the input signal VIN1. Similarly, a first terminal of the transistor MN2 is coupled to a second terminal of the transistor MP1, a second terminal of the transistor MN2 is coupled to a first terminal of the transistor MP2 to generate the output signal VO2, and a control terminal of the transistor MN2 receives the input signal VIN2. A second terminal of the transistor MP2 is coupled to the power node PN2 to receive the power voltage V2, and a control terminal of the transistor MP2 receives the input signal VIN2. In this example, the input signal VIN1 and the input signal VIN2 may be DC voltages, so that the source follower circuit 110 and the source follower circuit 120 may generate DC voltages having different levels (i.e., the output signal VO1 and the output signal VO2).

FIG. 2 illustrates a schematic diagram of an analog buffer device 200 according to some embodiments of the present disclosure. Compared with FIG. 1, the analog buffer device 200 further includes a level shifter circuit 210. The level shifter circuit 210 may adjust a DC level of an input signal VIN2 to generate an input signal VIN1. For example, according to actual application bias requirements, the level shifter circuit 210 may pull up the DC level of the input signal VIN2 to generate the input signal VIN1 having a higher DC level. In some embodiments, when the input signal VIN2 is an alternating current (AC) signal, the input signal VIN1 and the input signal VIN2 have the same or similar AC signal components and have different DC levels. For example, an amplitude of the AC signal component of the input signal VIN1 may be a predetermined multiple of an amplitude of the AC signal component of the input signal VIN2, where the predetermined multiple may be, but is not limited to, 0.8, 0.9, 1 or other arbitrary values. In some embodiments, the predetermined multiple may be determined according to the design of the level shifter circuit 210.

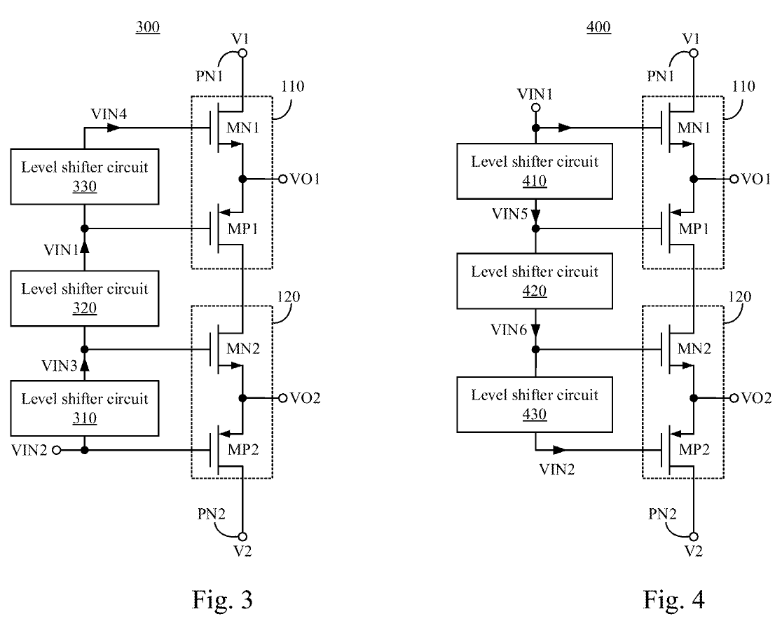

FIG. 3 illustrates a schematic diagram of an analog buffer device 300 according to some embodiments of the present disclosure. Compared with FIG. 1, the analog buffer device 300 further includes a level shifter circuit 310, a level shifter circuit 320 and a level shifter circuit 330, which may adjust a DC of an input signal VIN2 to sequentially generate an input signal VIN3, the input signal VIN1, and an input signal VIN4. In greater detail, the level shifter circuit 310 may adjust a DC level of the input signal VIN2 to generate the input signal VIN3. The level shifter circuit 320 may adjust a DC level of the input signal VIN3 to generate the input signal VIN1. The level shifter circuit 330 may adjust a DC level of the input signal VIN1 to generate the input signal VIN4. For example, according to actual application bias requirements, the level shifter circuit 310 may pull up the DC level of the input signal VIN2 to generate the input signal VIN3 having a higher DC level. Further, the level shifter circuit 320 may pull up the DC level of the input signal VIN3 to generate the input signal VIN1 having an even higher DC level. Finally, the level shifter circuit 330 may pull up the DC level of the input signal VIN1 to generate the input signal VIN4 having the highest DC level. In some embodiments, when the input signal VIN2 is an AC signal, the input signal VIN2 and the input signal VIN3 have the same or similar AC signal components and have different DC levels. Similarly, in some embodiments, when the input signal VIN1 is an AC signal, the input signal VIN1 and the input signal VIN4 have the same or similar AC signal components and have different DC levels. The above signal relationships may be referred to the relationship between the input signal VIN1 and the input signal VIN2 in FIG. 2 and will not be further given here.

In this example, the source follower circuit 110 further generates the output signal VO1 according to the input signal VIN1 and the input signal VIN4, and the source follower circuit 120 further generates the output signal VO2 according to the input signal VIN2 and the input signal VIN3. In greater detail, different from FIG. 1 or FIG. 2, a control terminal of the transistor MN1 receives the input signal VIN4, and a control terminal of the transistor MN2 receives the input signal VIN3. With the arrangement of the level shifter circuit 310, the level shifter circuit 320 and the level shifter circuit 330, the output signal VO1 and the output signal VO2 having different DC levels may be generated via the source follower circuit 110 and the source follower circuit 120 under different bias conditions. In some embodiments, the above output signal VO1 and output signal VO2 having different DC levels may serve as reference voltages or bias voltages for other circuits, but the present disclosure is not limited thereto.

FIG. 4 illustrates a schematic diagram of an analog buffer device 400 according to some embodiments of the present disclosure. Compared with FIG. 1 and FIG. 2, the analog buffer device 400 includes a level shifter circuit 410, a level shifter circuit 420 and, a level shifter circuit 430, which may adjust a DC level of an input signal VIN1 to sequentially generate an input signal VIN5, an input signal VIN6, and the input signal VIN2. In greater detail, the level shifter circuit 410 may adjust a DC level of the input signal VIN1 to generate the input signal VIN5. The level shifter circuit 420 may adjust a DC level of the input signal VIN5 to generate the input signal VIN6. The level shifter circuit 430 may adjust a DC level of the input signal VIN6 to generate the input signal VIN2. For example, according to actual application bias requirements, the level shifter circuit 410 may pull down the DC level of the input signal VIN1 to generate the input signal VIN5 having a lower DC level. Further, the level shifter circuit 420 may pull down the DC level of the input signal VIN5 to generate the input signal VIN6 having an even lower DC level. Finally, the level shifter circuit 430 may pull down the DC level of the input signal VIN6 to generate the input signal VIN2 having the lowest DC level. In some embodiments, when the input signal VIN1 is an AC signal, the input signal VIN1 and the input signal VIN5 have the same or similar AC signal components and have different DC levels. Similarly, in some embodiments, when the input signal VIN6 is an AC signal, the input signal VIN6 and the input signal VIN2 have the same or similar AC signal components and have different DC levels. The above signal relationships may be referred to the relationship between the input signal VIN1 and the input signal VIN2 in FIG. 2 and will not be further given here.

In this example, the source follower circuit 110 further generates the output signal VO1 according to the input signal VIN1 and the input signal VIN5, and the source follower circuit 120 further generates the output signal VO2 according to the input signal VIN2 and the input signal VIN6. In detail, different from `FIG. 1 or FIG. 2, a control terminal of the transistor MP1 receives the input signal VIN5, and a control terminal of the transistor MN2 receives the input signal VIN6. By arranging the level shifter circuit 410, the level shifter circuit 420 and the level shifter circuit 430, the output signal VO1 and the output signal VO2 having different DC levels may be generated via the source follower circuit 110 and the source follower circuit 120 under different bias conditions. Similarly, the above output signal VO1 and output signal VO2 having different DC levels may serve as reference voltages or bias voltages for other circuits, but the present case is not limited thereto.

From the arrangements shown in FIGS. 1 to 4, it is understood that, in some embodiments, the input signal VIN1 and the input signal VIN2 may be two different independent signals. Alternatively, in other embodiments, one of the input signal VIN1 and the input signal VIN2 may be generated based on another one of the input signal VIN1 and the input signal VIN2.

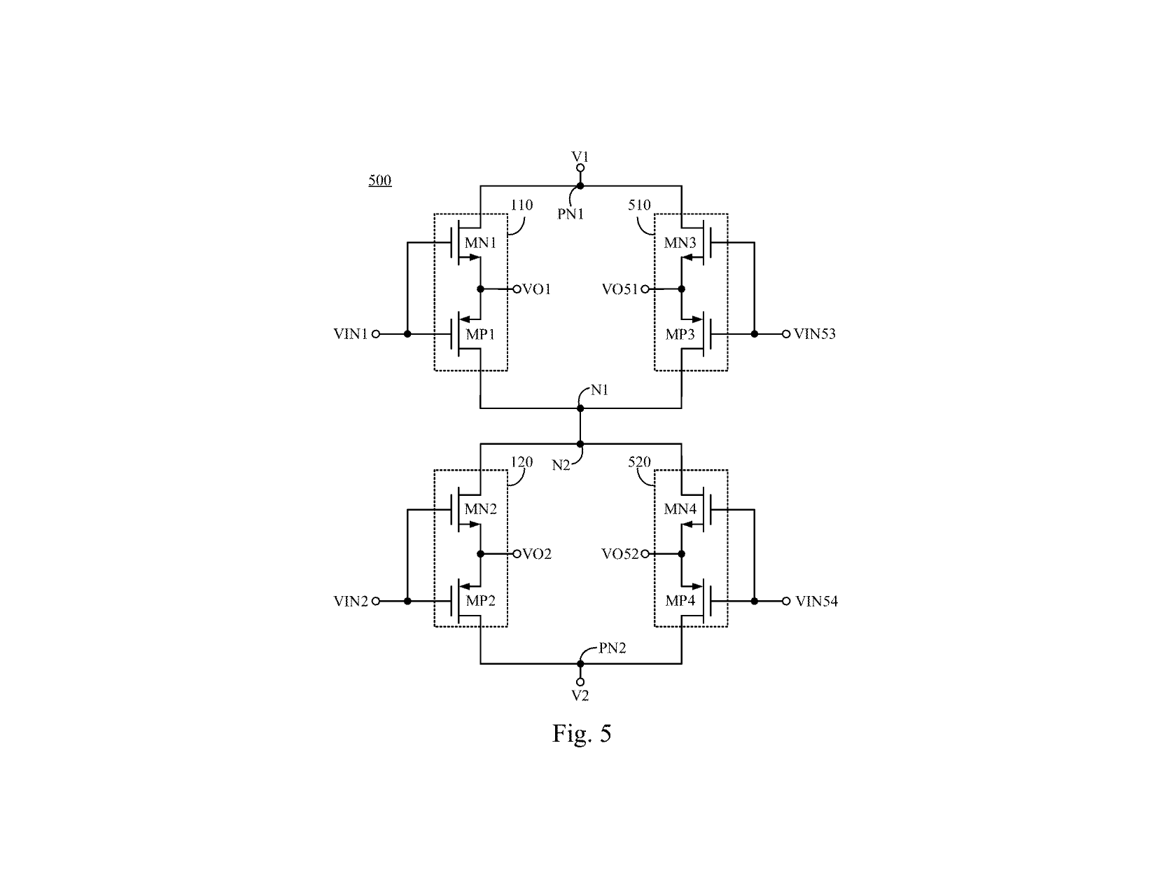

FIG. 5 illustrates a schematic diagram of an analog buffer device 500 according to some embodiments of the present disclosure. Compared with FIG. 1, the analog buffer device 500 further includes a source follower circuit 510 and a source follower circuit 520. The source follower circuit 510 generates an output signal VO51 according to an input signal VIN53, and the source follower circuit 520 generates an output signal VO52 according to an input signal VIN54. The source follower circuit 510 and the source follower circuit 110 are coupled in parallel between the power node PN1 and a node N1, and the source follower circuit 520 and the source follower circuit 120 are coupled in parallel between a node N2 and the power node PN2. The node N1 may be directly or indirectly coupled to the node N2, such that the source follower circuit 110, the source follower circuit 120, the source follower circuit 510 and the source follower circuit 520 may be biased by the same current flowing between the power node PN1 and the power node PN2.

In greater detail, the source follower circuit 510 includes a transistor MN3 and a transistor MP3, and the source follower circuit 520 includes a transistor MN4 and a transistor MP4. A first terminal of the transistor MN3 is coupled to the power node PN1 to receive the power voltage V1, a second terminal of the transistor MN3 is coupled to a first terminal of the transistor MP3 to generate the output signal VO51, and a control terminal of the transistor MN3 receives the input signal VIN53. A second terminal of the transistor MP3 is coupled to a second terminal of the transistor MP1 at the node N1, and a control terminal of the transistor MP3 receives the input signal VIN53. A first terminal of the transistor MN4 is coupled to a first terminal of the transistor MN2 at the node N1, a second terminal of the transistor MN4 is coupled to a first terminal of the transistor MP4 to generate the output signal VO52, and a control terminal of the transistor MN4 receives the input signal VIN54. A second terminal of the transistor MP4 is coupled to the power node PN2, and a control terminal of the transistor MP4 receives the input signal VIN54.

In some embodiments, the input signal VIN1, the input signal VIN2, the input signal VIN3 and the input signal VIN4 may be DC voltages. In some embodiments, the input signal VIN1 and the input signal VIN53 may be differential signals, and the input signal VIN2 and the input signal VIN54 may be differential signals. When the input signal VIN1 and the input signal VIN53 are differential signals, an AC signal component at the node N1 may be 0. Similarly, when the input signal VIN2 and the input signal VIN54 are differential signals, an AC signal component at the node N2 may be 0. For example, the input signal VIN1 may be expressed as VCM+ΔV, and the input signal VIN53 may be expressed as VCM-ΔV, where VCM is a DC common mode level of the input signal VIN1 and the input signal VIN53, and ΔV is an AC signal component. Through the coupling of the transistor MP1 and the transistor MP3, the AC signal component ΔV may be cancelled at the node N1, thereby making the AC signal component at the node N1 substantially zero. Similarly, the AC signal component at the node N2 may be cancelled out to 0 through the coupling of the transistor MN2 and the transistor MN4. Thus, by the above arrangement, the two nodes N1 and N2 with an AC signal component of 0 may be formed, thereby connecting the upper and lower groups of the source follower circuits (that is, the source follower circuits 110 and 510 between the power node PN1 and the node N1 form one group, and the source follower circuits 120 and 520 between the power node PN2 and the node N2 form another group) together and biasing those groups with the same current. In some embodiments, the input signal VIN53 and the input signal VIN54 may be the same signal.

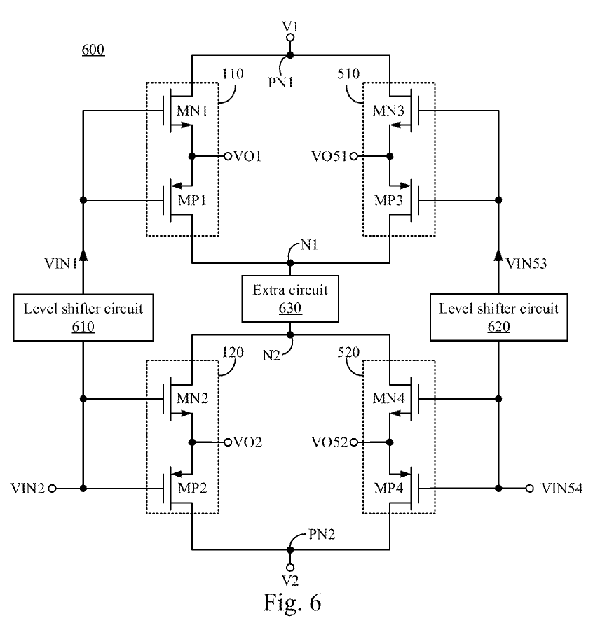

FIG. 6 illustrates a schematic diagram of an analog buffer device 600 according to some embodiments of the present disclosure. Compared with FIG. 5, the analog buffer device 600 further includes a level shifter circuit 610, a level shifter circuit 620 and an extra circuit 630. The level shifter circuit 610 is used to adjust a DC level of an input signal VIN2 to generate an input signal VIN1, and the level shifter circuit 620 is used to adjust a DC level of an input signal VIN54 to generate an input signal VIN53. For example, according to actual application bias requirements, the level shifter circuit 610 may shift the DC level of the input signal VIN2 to generate the input signal VIN1 having a higher DC level. Similarly, the level shifter circuit 620 may pull up the DC level of the input signal VIN54 to generate the input signal VIN53 having a higher DC level. In some embodiments, when the input signal VIN2 is an AC signal, the input signal VIN1 and the input signal VIN2 have the same or similar AC signal components and have different DC levels. Similarly, in some embodiments, when the input signal VIN54 is an AC signal, the input signal VIN54 and the input signal VIN53 have the same or similar AC signal components and have different DC levels. The above signal relationships may be referred to the relationship between the input signal VIN1 and the input signal VIN2 in FIG. 2 and will not be further given here.

On the other hand, in this example, the node N1 is further coupled to the node N2 via the extra circuit 630. In some embodiments, the extra circuit 630 may be configured to adjust internal levels in the analog buffer device 600, so that each node level in the analog buffer device 600 meets design requirements. In some embodiments, the extra circuit 630 may include, but not limited to, resistive elements. It is understood that in different embodiments, the analog buffer device 500 in FIG. 5 may also be provided with the extra circuit 630.

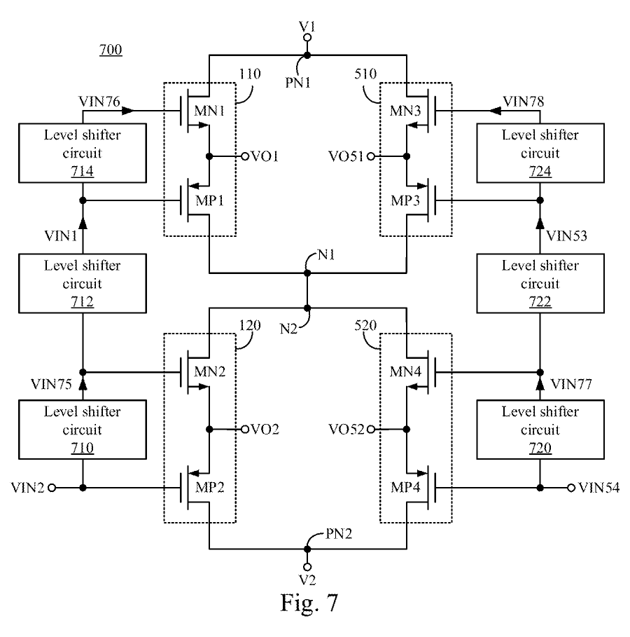

FIG. 7 illustrates a schematic diagram of an analog buffer device 700 according to some embodiments of the present disclosure. Compared with FIG. 5, the analog buffer device 700 further includes a level shifter circuit 710, a level shifter circuit 712, a level shifter circuit 714, a level shifter circuit 720, a level shifter circuit 722 and a level shifter circuit 724. The level shifter circuit 710, the level shifter circuit 712 and the level shifter circuit 714 are configured to adjust a DC level of an input signal VIN2 to sequentially generate an input signal VIN75, an input signal VIN1 and an input signal VIN76. For example, the level shifter circuit 710 may adjust a DC level of the input signal VIN2 to generate the input signal VIN75, the level shifter circuit 712 may adjust a DC level of the input signal VIN75 to generate the input signal VIN1, and the level shifter circuit 714 may adjust a DC level of the input signal VIN1 to generate the input signal VIN76. Similarly, the level shifter circuit 720, the level shifter circuit 722 and the level shifter circuit 724 are used to adjust a DC level of an input signal VIN54 to sequentially generate an input signal VIN77, an input signal VIN53 and an input signal VIN78. For example, the level shifter circuit 720 may adjust a DC level of the input signal VIN54 to generate the input signal VIN77, the level shifter circuit 722 may adjust a DC level of the input signal VIN77 to generate the input signal VIN53, and the level shifter circuit 724 may adjust a DC level of the input signal VIN53 to generate the input signal VIN78.

In some embodiments, when the input signal VIN2 is an AC signal, the input signal VIN2 and the input signal VIN75 have the same or similar AC signal components and have different DC levels. In some embodiments, when the input signal VIN75 is an AC signal, the input signal VIN75 and the input signal VIN1 have the same or similar AC signal components and have different DC levels. In some embodiments, when the input signal VIN1 is an AC signal, the input signal VIN1 and the input signal VIN76 have the same or similar AC signal components and have different DC levels. Similarly, in some embodiments, when the input signal VIN54 is an AC signal, the input signal VIN54 and the input signal VIN77 have the same or similar AC signal components and have different DC levels. In some embodiments, when the input signal VIN77 is an AC signal, the input signal VIN53 and the input signal VIN77 have the same or similar AC signal components and have different DC levels. In some embodiments, when the input signal VIN53 is an AC signal, the input signal VIN53 and the input signal VIN78 have the same or similar AC signal components and have different DC levels. The above signal relationships may be referred to the relationship between the input signal VIN1 and the input signal VIN2 in FIG. 2 and will not be further given here.

In this example, the source follower circuit 110 further generates the output signal VO1 according to the input signal VIN1 and the input signal VIN76, the source follower circuit 120 further generates the output signal VO2 according to the input signal VIN2 and the input signal VIN75, the source follower circuit 510 further generates the output signal VO51 according to the input signal VIN53 and the input signal VIN78, and the source follower circuit 520 further generates the output signal VO52 according to the input signal VIN54 and the input signal VIN77. In detail, different from FIG. 5, a control terminal of the transistor MN1 receives the input signal VIN76, a control terminal of the transistor MN2 receives the input signal VIN75, a control terminal of the transistor MN3 receives the input signal VIN78, and a control terminal of the transistor MN4 receives the input signal VIN77. As a result, the analog buffer device 700 may generate the output signal VO1, the output signal VO2, the output signal VO51 and the output signal VO52 having different DC levels under different bias conditions.

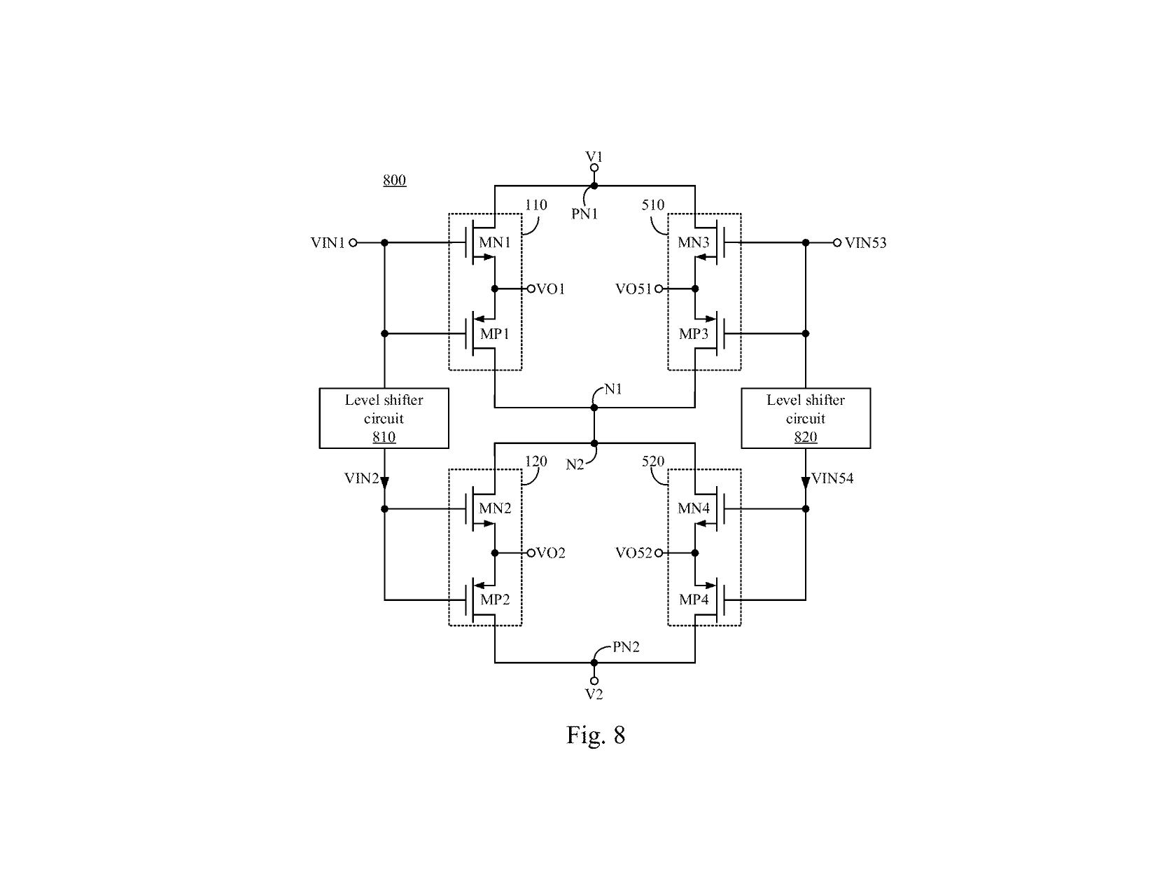

FIG. 8 illustrates a schematic diagram of an analog buffer device 800 according to some embodiments of the present disclosure. Compared with FIG. 5, the analog buffer device 800 further includes a level shifter circuit 810 and a level shifter circuit 820. The level shifter circuit 810 is used to adjust an input signal VIN1 to generate an input signal VIN2, and the level shifter circuit 820 is used to adjust an input signal VIN53 to generate an input signal VIN54. For example, according to actual application bias requirements, the level shifter circuit 810 may pull down a DC level of the input signal VIN1 to generate the input signal VIN2 having a lower DC level. Similarly, the level shifter circuit 820 may pull down a DC level of the input signal VIN53 to generate the input signal VIN54 having a lower DC level. In some embodiments, when the input signal VIN1 is an AC signal, the input signal VIN1 and the input signal VIN2 have the same or similar AC signal components and have different DC levels. Similarly, in some embodiments, when the input signal VIN53 is an AC signal, the input signal VIN53 and the input signal VIN54 have the same or similar AC signal components and have different DC levels. The above signal relationships may be referred to the relationship between the input signal VIN1 and the input signal VIN2 in FIG. 2 and will not be further given here.

From the arrangements shown in FIGS. 5 to 8, it is understood that, in some embodiments, the input signal VIN1 and the input signal VIN53 may be differential signals, and the input signal VIN2 and the input signal VIN54 may be differential signals. One of the input signal VIN1 and the input signal VIN2 may be generated based on another one of the input signal VIN1 and the input signal VIN2, and one of the input signal VIN53 and the input signal VIN54 may be generated based on another one of the input signal VIN53 and the input signal VIN54.

The arrangements shown in the above embodiments are given for illustrative purposes, and the present disclosure are not limited thereto. It is understood that, based on actual application requirements, different numbers of level shifter circuits and/or different numbers of extra circuits may be employed in the above embodiments.

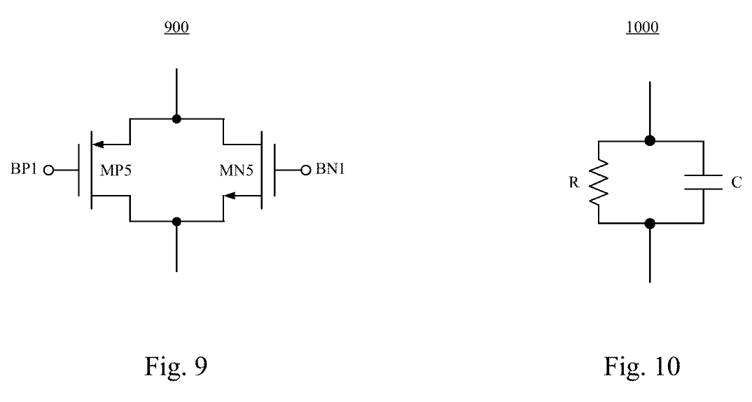

FIG. 9 illustrates a schematic diagram of a level shifter circuit 900 according to some embodiments of the present disclosure. The level shifter circuits in the above figures may be implemented with the level shifter circuit 900. The level shifter circuit 900 includes a transistor MP5 and a transistor MN5. A first terminal of the transistor MP5 is coupled to a first terminal of the transistor MN5, a second terminal of the transistor MP5 is coupled to a second terminal of the transistor MN5, a control terminal of the transistor MP5 receives a bias voltage BP1, and a control terminal of the transistor MN5 receives a bias voltage BN1. The transistor MP5 and the transistor MN5 may operate as a resistor for level shifting.

FIG. 10 illustrates a schematic diagram of a level shifter circuit 1000 according to some embodiments of the present disclosure. The level shifter circuits in the above figures may be implemented with the level shifter circuit 1000. The level shifter circuit 1000 includes a resistor R and a capacitor C. The resistor R and the capacitor C are coupled in parallel, where the resistor R is configured to adjust a DC level, and the capacitor C is configured to couple an AC signal component.

The arrangements shown in FIG. 9 and FIG. 10 are given for illustrative purposes, and the present disclosure is not limited thereto. Various types of level shifter circuits are within the contemplated scope of the present disclosure.

As described above, the analog buffer devices provided by some embodiments of the present disclosure may utilize the same current to bias source follower circuits, in order to generate buffered output signals while reusing the bias current.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically include transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely some embodiments of the present disclosure, without any intention to limit the scope of the present disclosure thereto. Various equivalent changes, alterations, or modifications according to the claims of present disclosure are all consequently viewed as being embraced by the scope of the present disclosure.

What is claimed is:

1. An analog buffer device, comprising:
a first source follower circuit configured to generate a first output signal according to a first input signal; and
a second source follower circuit configured to generate a second output signal according to a second input signal,
wherein the first source follower circuit and the second source follower circuit are coupled in series and coupled between a first power node and a second power node, the first power node receives a first power voltage, and the second power node receives a second power voltage.

2. The analog buffer device of claim 1, further comprising:
a third source follower circuit configured to generate a third output signal according to a third input signal,
wherein the first source follower circuit and the third source follower circuit are coupled in parallel between the first power node and a first node; and
a fourth source follower circuit configured to generate a fourth output signal according to a fourth input signal,
wherein the second source follower circuit and the fourth source follower circuit are coupled in parallel between a second node and the second power node, and the first node is coupled to the second node.

3. The analog buffer device of claim 2, wherein an alternating-current (AC) signal component at the first node is substantially zero.

4. The analog buffer device of claim 2, wherein the first node is further coupled to the second node via an extra circuit.

5. The analog buffer device of claim 2, further comprising:
a first level shifter circuit configured to adjust a direct current (DC) level of the second input signal to generate the first input signal; and
a second level shifter circuit configured to adjust a DC level of the fourth input signal to generate the third input signal.

6. The analog buffer device of claim 2, further comprising:
a plurality of first level shifter circuits configured to adjust a DC level of the second input signal to sequentially generate a fifth input signal, the first input signal, and a sixth input signal; and
a plurality of second level shifter circuits configured to adjust a DC level of the fourth input signal to sequentially generate a seventh input signal, the third input signal, and an eighth input signal,
wherein the first source follower circuit further generates the first output signal according to the first input signal and the sixth input signal, the second source follower circuit further generates the second output signal according to the second input signal and the fifth input signal, the third source follower circuit further generates the third output signal according to the third input signal and the eighth input signal, and the fourth source follower circuit further generates the fourth output signal according to the fourth input signal and the seventh input signal.

7. The analog buffer device of claim 6, wherein the plurality of first level shifter circuits are configured to adjust a DC level of the second input signal to generate the fifth input signal, adjust a DC level of the fifth input signal to generate the first input signal, and adjust a DC level of the first input signal to generate the sixth input signal.

8. The analog buffer device of claim 6, wherein the second level shifter circuits are used to adjust a DC level of the fourth input signal to generate the seventh input signal, to adjust a DC level of the seventh input signal to generate the third input signal, and to adjust a DC level of the third input signal to generate the eighth input signal.

9. The analog buffer device of claim 2, further comprising:
a first level shifter circuit configured to adjust a DC level of the first input signal to generate the second input signal; and
a second level shifter circuit configured to adjust a DC level of the third input signal to generate the fourth input signal.

10. The analog buffer device of claim 2, wherein an AC signal component at the second node is substantially zero.

11. The analog buffer device of claim 2, wherein the first input signal and the third input signal are differential signals.

12. The analog buffer device of claim 2, wherein the second input signal and the fourth input signal are differential signals.

13. The analog buffer device of claim 2, wherein the third input signal and the fourth input signal are the same signal.

14. The analog buffer device of claim 1, further comprising: a level shifter circuit configured to adjust a DC level of the second input signal to generate the first input signal.

15. The analog buffer device of claim 1, further comprising:
a plurality of level shifter circuits configured to a DC level of the second input signal to sequentially generate a third input signal, the first input signal, and a fourth input signal,
wherein the first source follower circuit further generates the first output signal according to the first input signal and the fourth input signal, and the second source follower circuit further generates the second output signal according to the second input signal and the third input signal.

16. The analog buffer device of claim 15, wherein the plurality of level shifter circuits comprise:
a first level shifter circuit configured to adjust a DC level of the second input signal to generate the third input signal;
a second level shifter circuit configured to adjust a DC level of the third input signal to generate the first input signal; and
a third level shifter circuit configured to adjust a DC level of the first input signal to generate the fourth input signal.

17. The analog buffer device of claim 1, further comprising:
a plurality of level shifter circuits configured to adjust a DC level of the first input signal to sequentially generate a fifth input signal, a sixth input signal, and the second input signal,
wherein the first source follower circuit further generates the first output signal according to the first input signal and the fifth input signal, and the second source follower circuit further generates the second output signal according to the second input signal and the sixth input signal.

18. The analog buffer device of claim 17, wherein the level shifter circuits comprise:
a first level shifter circuit configured to adjust a DC level of the first input signal to generate the fifth input signal;
a second level shifter circuit configured to adjust a DC level of the fifth input signal to generate the sixth input signal; and
a third level shifter circuit configured to adjust a DC level of the sixth input signal to generate the second input signal.

19. The analog buffer device of claim 1, wherein the first input signal and the second input signal are the same signal.

20. The analog buffer device of claim 1, wherein the first input signal and the second input signal are DC voltages.
